(19) United States
(12) Patent Application Publication
(10) Pub. No.: US 2009/0020756 A1
(43) Pub. Date: Jan. 22, 2009

(54) Test structures of a semiconductor device and methods of forming the same

(75) Inventor: Jae-Pil Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/219,280

(22) Filed: Jul. 18, 2008

(30) Foreign Application Priority Data
Jul. 20, 2007 (KR) 10-2007-72720

(51) Int. Cl. H01L 23/58; H01L 21/84

(52) U.S. Cl. 257/48; 438/155; 257/E23.002; 257/E21.7

(57) ABSTRACT

A test structure including a transistor, a conductive pattern and a pad unit is provided. The transistor may be formed on a substrate having circuit patterns. The conductive pattern is electrically connected to the transistor. The conductive pattern may be used in aligning the circuit patterns and/or sensing plasma damage to the semiconductor device. The conductive pattern may be used in reducing etching damage to the circuit patterns and sensing plasma damage to the semiconductor device. The pad unit is electrically connected to the transistor, and provides electrical signals to the transistor. The conductive pattern may serve as an antenna pattern and/or an align/overlay pattern or a dummy pattern.

### PRIORITY STATEMENT

This application claims the benefit of priority under 35 USC §119 to Korean Patent Application No. 2007-72720, filed on Jul. 20, 2007 in the Korean Intellectual Property Office (KIPO), the contents of which are herein incorporated by reference in their entirety.

### BACKGROUND

1. Field

Example embodiments relate to test structures of a semiconductor device and methods of forming the same. Other example embodiments relate to test structures of a semiconductor device for measuring plasma damage to the semiconductor device and methods of forming the same.

2. Description of the Related Art

In a method of manufacturing a semiconductor device, a photolithography technique may be necessary. The photolithography technique includes etching processes (e.g., a plasma etching process, a reactive ion etching (RIE) process or similar processes). Due to the higher integration degree of semiconductor devices, plasma etching processes (e.g., a high density plasma etching process) have been widely used in order to form various structures having a smaller critical dimension. However, if the high density plasma process is performed, a substantially strong magnetic field is generated between a substrate and a gate structure. The strong magnetic field damage a gate insulation layer in the gate structure, thereby reducing the reliability of the semiconductor device. In order to measure the plasma damage to the semiconductor device, test structures (e.g., test element group (TEG) patterns) may be formed in a scribe lane region of a substrate on which the semiconductor device is formed.

In addition to the TEG patterns, align patterns and overlay patterns for aligning various circuit patterns may be formed in the scribe lane region. Due to the number of TEG patterns and align/overlay patterns formed in the scribe lane region, it may be necessary to form the scribe lane with a larger area. As such, the semiconductor device may not have a high integration degree. If patterns are formed by a chemical mechanical polishing (CMP) process, dummy patterns for preventing the patterns from being damaged may be formed in the scribe lane region, or a net die region.

Reducing the area of the scribe lane region in which the TEG patterns, the align/overlay patterns and the dummy patterns are formed may be necessary in order to realize a semiconductor device having a higher integration degree.

### SUMMARY

Example embodiments relate to a test structure of a semiconductor device and a method of forming the same. Other example embodiments relate to a test structure of a semiconductor device for measuring plasma damage to the semiconductor device and a method of forming the same.

Example embodiments provide a test structure of a semiconductor device, wherein the test structure is more efficiently disposed in a substantially small area.

Example embodiments provide a method of forming a test structure of a semiconductor device, wherein the test structure is more efficiently disposed in a small area.

According to example embodiments, there is provided a test structure of a semiconductor device. The structure includes a transistor, a conductive pattern and a pad unit. The transistor may be formed on a substrate having circuit patterns. The conductive pattern is electrically connected to the transistor. The conductive pattern may be used in aligning the circuit patterns and sensing plasma damage to the semiconductor device. The pad unit is electrically connected to the transistor, and provides electrical signals to the transistor.

In example embodiments, the transistor may include a gate line, and the conductive pattern may be electrically connected to the gate line.

In example embodiments, the test structure may include a bit line electrically connected to the transistor. The conductive pattern may be electrically connected to the bit line.

In example embodiments, the conductive pattern may include a gate antenna pattern and a bit line antenna pattern. The test structure may include a plug connecting the gate antenna pattern and the bit line antenna pattern. In example embodiments, a plurality of the plugs may be formed.

In example embodiments, the conductive pattern may include a plurality of first conductive lines and a second conductive line. Each of the first conductive lines may extend in a first direction. The first conductive lines may be disposed at a given (or desired) distance from each other in a second direction substantially perpendicular to the first direction. The second conductive line may extend in the second direction and connect the first conductive lines to each other.

According to example embodiments, there is provided a test structure of a semiconductor device. The test structure includes a transistor, a conductive pattern and a pad unit. The transistor may be formed on a substrate having circuit patterns. The conductive pattern is electrically connected to the transistor. The conductive pattern may be used in reducing etching damage to the circuit patterns and sensing plasma damage to the semiconductor device. The pad unit is electrically connected to the transistor, and provides electrical signals to the transistor.

In example embodiments, the transistor may include a gate line. The conductive pattern may be electrically connected to the gate line.

In example embodiments, the test structure may include a bit line electrically connected to the transistor. The conductive pattern may be electrically connected to the bit line.

In example embodiments, the conductive pattern may include a gate antenna pattern and a bit line antenna pattern. The test structure may include a plug connecting the gate antenna pattern and the bit line antenna pattern. In example embodiments, a plurality of the plugs may be formed.

In example embodiments, the conductive pattern may include a plurality of first conductive lines and a second conductive line. Each of the first conductive lines may extend in a first direction, and the first conductive lines may be disposed at a given (or desired) distance from each other in a second direction substantially perpendicular to the first direction. The second conductive line may extend in the second direction and connect the first conductive lines to each other.

According to example embodiments, there is provided a method of forming a test structure of a semiconductor device. In the method, a transistor may be formed on a substrate having circuit patterns. A conductive pattern, which is electrically connected to the transistor and used in aligning the circuit patterns and/or sensing plasma damage to the semiconductor device, is formed. A pad unit, which is electrically connected to the transistor and provides electrical signals to the transistor, may be formed.

In example embodiments, if the transistor is formed, a gate line may be formed. The conductive pattern may be electrically connected to the gate line.

In example embodiments, a bit line electrically connected to the transistor may be formed. The conductive pattern may be electrically connected to the bit line.

In example embodiments, if the conductive pattern is formed, a gate antenna pattern and a bit line antenna pattern may be formed. A plug connecting the gate antenna pattern and the bit line antenna pattern may be formed. In example embodiments, a plurality of the plugs may be formed.

In example embodiments, if the conductive pattern is formed, a plurality of first conductive lines may be formed. Each of the first conductive lines may extend in a first direction, and the first conductive lines may be disposed at a given (or desired) distance from each other in a second direction substantially perpendicular to the first direction. A second conductive line may be formed. The second conductive line may extend in the second direction. The second conductive line may connect the first conductive lines to each other.

According to example embodiments, there is provided a method of forming a test structure of a semiconductor device. In the method, a transistor is formed on a substrate having circuit patterns. A conductive pattern, which is electrically connected to the transistor and used in reducing etching damage to the circuit patterns and/or sensing plasma damage to the semiconductor device, is formed. A pad unit, which is electrically connected to the transistor and provides electrical signals to the transistor, may be formed.

In example embodiments, if the transistor is formed, a gate line may be formed. The conductive pattern may be electrically connected to the gate line.

In example embodiments, a bit line electrically connected to the transistor may be formed. The conductive pattern may be electrically connected to the bit line.

In example embodiments, if the conductive pattern is formed, a gate antenna pattern and a bit line antenna pattern may be formed. A plug connecting the gate antenna pattern and the bit line antenna pattern may be formed. In example embodiments, a plurality of the plugs may be formed.

In example embodiments, if the conductive pattern is formed, a plurality of first conductive lines is formed. Each of the first conductive lines may extend in a first direction. The first conductive lines may be disposed at a given (or desired) distance from each other in a second direction substantially perpendicular to the first direction. The second conductive line may extend in the second direction and connect the first conductive lines to each other.

According to example embodiments, a conductive pattern included in a test structure of a semiconductor device may serve (or function) not only as an antenna for sensing plasma damage to the semiconductor device, but also as an align/overlay pattern for aligning various circuit patterns on the net die region. The conductive pattern may serve (or function) as a dummy pattern for reducing etching damage to the circuit patterns. Thus, a scribe lane region of a substrate, on which the test structure, the align/overlay pattern and the dummy pattern are formed, may have a reduced area such that the semiconductor device including the elements on the scribe lane region may have a higher integration degree. If the test structure, the align/overlay pattern and the dummy pattern are formed on a net die region of the substrate, the net die region may have a relatively reduced area such that the semiconductor device may have a higher integration degree.

### BRIEF DESCRIPTION OF THE DRAWINGS

Example embodiments will be more clearly understood from the following detailed description taken in conjunction with the accompanying drawings. FIGS. 1-8, 9A-9D and 10A-10D represent non-limiting, example embodiments as described herein.

FIG. 1 is a top view illustrating a test structure of a semiconductor device in accordance with example embodiments;

FIG. 2 is a cross-sectional view taken along the line I-I′ of FIG. 1;

FIG. 3 is a top view illustrating a test structure of a semiconductor device in accordance with example embodiments;

FIG. 4 is a cross-sectional view taken along the line II-II′ of FIG. 3;

FIG. 5 is a top view illustrating a test structure of a semiconductor device in accordance with example embodiments;

FIG. 6 is a top view illustrating a test structure of a semiconductor device in accordance with example embodiments;

FIG. 7 is a top view illustrating a test structure of a semiconductor device in accordance with example embodiments;

FIG. 8 is a top view illustrating a test structure of a semiconductor device in accordance with example embodiments;

FIGS. 9A to 9D are top views illustrating a method of forming a test structure of a semiconductor device in accordance with example embodiments; and

FIGS. 10A to 10D are top views illustrating a method of forming a test structure of a semiconductor device in accordance with example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to test structures of a semiconductor device and methods of forming the same. Other example embodiments relate to test structures of a semiconductor device for measuring plasma damage to the semiconductor device and methods of forming the same.

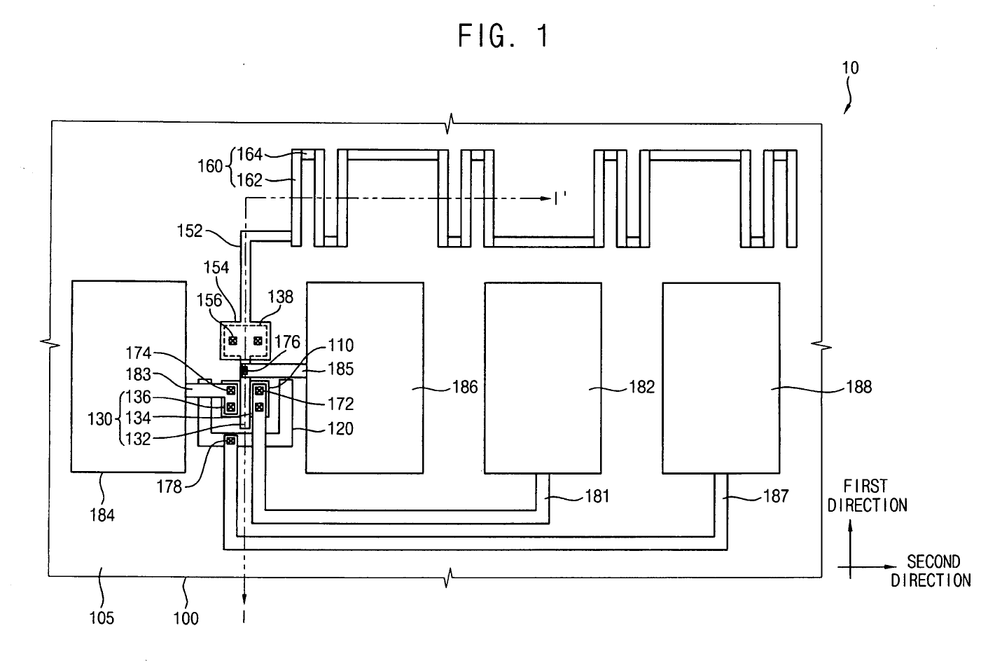

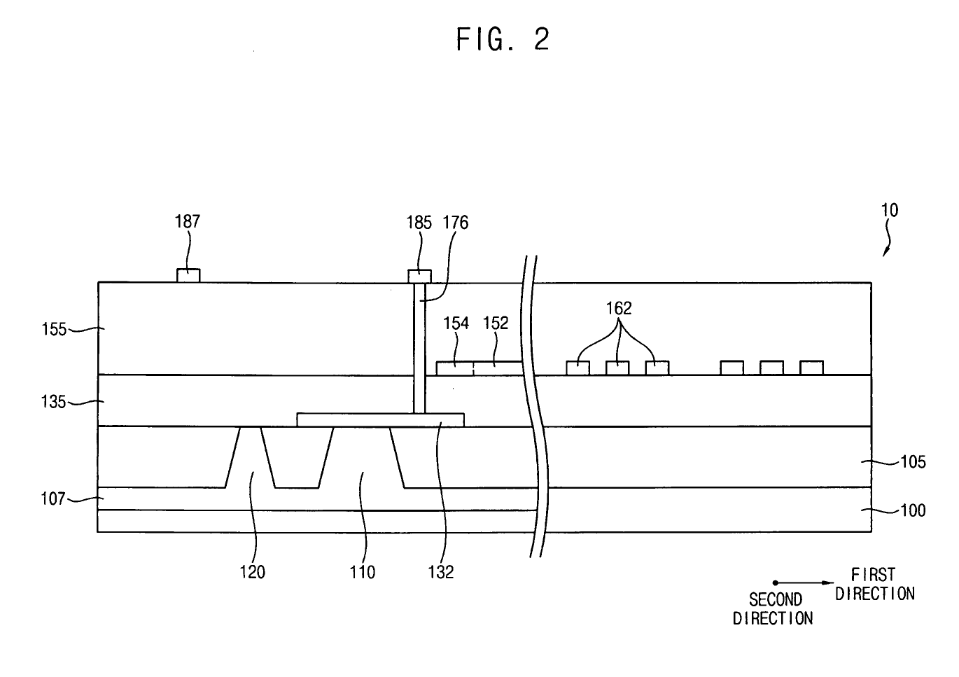

FIG. 1 is a top view illustrating a test structure of a semiconductor device in accordance with example embodiments, and FIG. 2 is a cross-sectional view taken along the line I-l′ of FIG. 1.

Referring to FIGS. 1 and 2, a test structure 10 of the semiconductor device includes a transistor 130 on a substrate 100, a first conductive pattern 160 and a pad unit. The test structure 10 may include a bit line 152.

The substrate 100 may include a semiconductor substrate on which semiconductor devices are formed, a glass substrate on which integrated circuits for a flat panel display device are formed, or a like substrate. The substrate 100 may include a silicon substrate, a germanium substrate, a silicon-germanium substrate, a silicon-on-insulator (SOI) substrate, a germanium-on-insulator (GOI) substrate, or the like. The substrate 100 may be divided into (or defined by) a net die region and a scribe lane region. In example embodiments, the test structure 10 of the semiconductor device may be formed on the scribe lane region. Alternatively, the test structure 10 of the semiconductor device may be formed on the net die region.

The substrate 100 may be divided into (or defined by) a field region and an active region. An isolation layer 105 may be formed in the field region. The isolation layer 105 may include silicon oxide. The active region has a first active region 110 and a second active region 120.

The transistor 130 includes a gate line 132 on the first active region 110, and a source region 134 and a drain region 136 at upper portions of the first active region 110 adjacent to the gate line 132.

The gate line 132 includes a gate insulation layer (not shown) and a gate electrode (not shown). The gate insulation layer may include silicon oxide or a metal oxide. The gate electrode may include polysilicon doped with impurities, a metal and/or a metal silicide. Gate spacers (not shown) including silicon nitride or silicon oxynitride may be formed on sidewalls of the gate line 132. In example embodiments, the gate line 132 extends in a first direction. The gate line 132 may be formed on (or extend to) an outside area of the first active region 110. A gate line pad 138 may be formed at one end of the gate line 132 such that the gate line 132 may be connected to the bit line 152. The gate line pad 138 may include a material substantially the same as that of the gate line 132.

The source and drain regions 134 and 136 may include P-type impurities (e.g., boron, gallium, indium, or the like) or N-type impurities (e.g., phosphorus, arsenic, antimony, or the like).

The transistor 130 may have a configuration substantially the same as, or similar to, that of a cell transistor on the net die region. The transistor 130 may be used to measure plasma damage to the semiconductor device sensed by the first conductive pattern 160.

Although one transistor 130 is shown in FIGS. 1 and 2, a plurality of transistors 130 may be also formed.

The bit line 152 may transfer electrical signals to the transistor 130. The bit line may include a conductive material (e.g., a metal and/or a metal nitride). A bit line pad 154 may be formed at one end of the bit line 152. The bit line pad 154 and the gate line pad 138 are electrically connected to each other by a bit line plug 156. The bit line plug 156 may be formed through a first insulating interlayer 135, which is formed on the substrate 100 to cover the gate line 132. The bit line 152 and the bit line pad 154 may be formed on the first insulating interlayer 135. The bit line pad 156 may include a conductive material (e.g., a metal and/or a metal nitride). The first insulating interlayer 135 may include an oxide, a nitride and/or an oxynitride.

The first conductive pattern 160 includes a first conductive line 162 and a second conductive line 164. In example embodiments, a plurality of the first conductive lines 162 may be formed. Each of the first conductive lines 162 extends in the first direction. The second conductive line 164 connects the first conductive lines 162 to each other. In example embodiments, a plurality of the second conductive lines 164 may be formed. Each of the second conductive lines 164 extends in a second direction substantially perpendicular to the first direction.

The first conductive pattern 160, particularly, the first conductive line 162 may be used in aligning various circuit patterns formed on the net die region of the substrate 100. If the circuit patterns are formed in a plurality of layers, the first conductive pattern 160 may be used in vertically aligning the circuit patterns. As such, the first conductive pattern 160 may serve (or function) as an align pattern or an overlay pattern.

The first conductive pattern 160 may serve (or function) as an antenna sensing plasma damage to the test structure of the semiconductor device. The first conductive pattern 160 may be referred to as a bit line antenna pattern. For example, in order to measure plasma damage to the semiconductor device during an etching process using plasma (e.g., a high density plasma etching process), the first conductive pattern 160 may sense the plasma damage. A gate insulation layer of a transistor is influenced (or affected) by the plasma damage such that the first conductive pattern 160 is connected to the gate line 132 of the transistor 130. In example embodiments, the first conductive pattern 160 is connected to the gate line 132 by the bit line 152, the bit line pad 154, the bit line plug 156 and the gate line pad 138.

The first conductive pattern 160 may have various shapes if only (or as long as) the first conductive pattern 160 serves (or functions) simultaneously as an align/overlay pattern and an antenna. Even though the first conductive pattern 160 has a zigzag shape in FIG. 1, the second conductive line 164 may have a long bar (or rectangular) shape extending in the second direction, and connects ends of the first conductive lines 162 that are adjacent (or located at the same side). In this case, the first conductive pattern 160 may have a comb-like shape. The first conductive pattern 160 may have any shape if only (or as long as) each portion of the first conductive pattern 160 is connected to each other, and the first conductive pattern 160 is connected to the gate line 132.

The pad unit includes a source pad 182, a drain pad 184, a gate pad 186 and a bulk pad 188. The pads 182, 184, 186 and 188 may include a conductive material (e.g., a metal and/or a metal nitride). The pads 182, 184, 186 and 188 may be formed on a second insulating interlayer 155. The second insulating interlayer 155 may be formed on the first insulating interlayer 135 to cover the bit line 152, the bit line pad 154 and the first conductive pattern 160. The second insulating interlayer 155 may include an oxide, a nitride and/or an oxynitride.

The source pad 182 may be connected to the source region 134 by a source pad connection line 181 on the second insulating interlayer 155 and a first plug 172 through the first and second insulating interlayers 135 and 155. The drain pad 184 may be connected to the drain region 136 by a drain pad connection line 183 on the second insulating interlayer 155 and a second plug 174 through the first and second insulating interlayers 135 and 155. The gate pad 186 may be connected to the gate line 132 by a gate pad connection line 185 on the second insulating interlayer 155 and a third plug 176 through the first and second insulating interlayers 135 and 155. The bulk pad 188 may be connected to the second active region 120 by a bulk pad connection line 187 on the second insulating interlayer 155 and a fourth plug 178 through the first and second insulating interlayers 135 and 155. The connection lines 181, 183, 185 and 187 and the first to fourth plugs 172, 174, 176 and 178 may include a conductive material (e.g., a metal and/or a metal nitride).

The second active region 120 may be formed at a portion of the substrate 100. In example embodiments, the second active region may be formed at a peripheral area of the first active region 110. The second active region 120 may serve (or function) as a path by which electrical signals pass. The electrical signals may be applied to a well region 107 formed at a portion of the substrate 100. Electrical signals applied to the bulk pad 188 may pass by the bulk pad connection line 187, the fourth plug 178 and the second active region 120, and may be applied to the well region 107. The well region 107 may include P-type, or N-type, impurities.

The order and the locations of the pads 182, 184, 186 and 188 may be changed.

Various wirings may be formed on, or over, the substrate 100.

In the test structure of the semiconductor device having the above elements, the first conductive pattern 160 may serve (or function) not only as an antenna for sensing plasma damage, but also as an align/overlay pattern for aligning various circuit patterns on the net die region. The scribe lane region on which the test structure and the align/overlay pattern are formed may have a reduced area. As such, the semiconductor device may have a higher integration degree. If a semiconductor device includes a test structure and an align/overlay pattern on a net die region, a net die region in accordance with example embodiment may have a relatively smaller area compared to that on which the test structure and the align/overlay pattern are formed independently. As such, the semiconductor device according to example embodiments may have a higher integration degree.

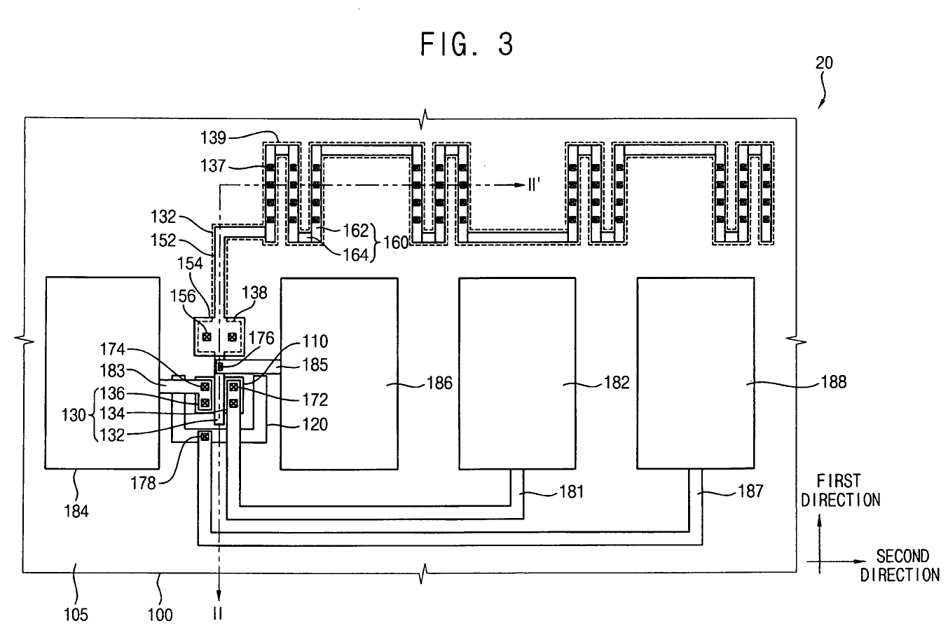

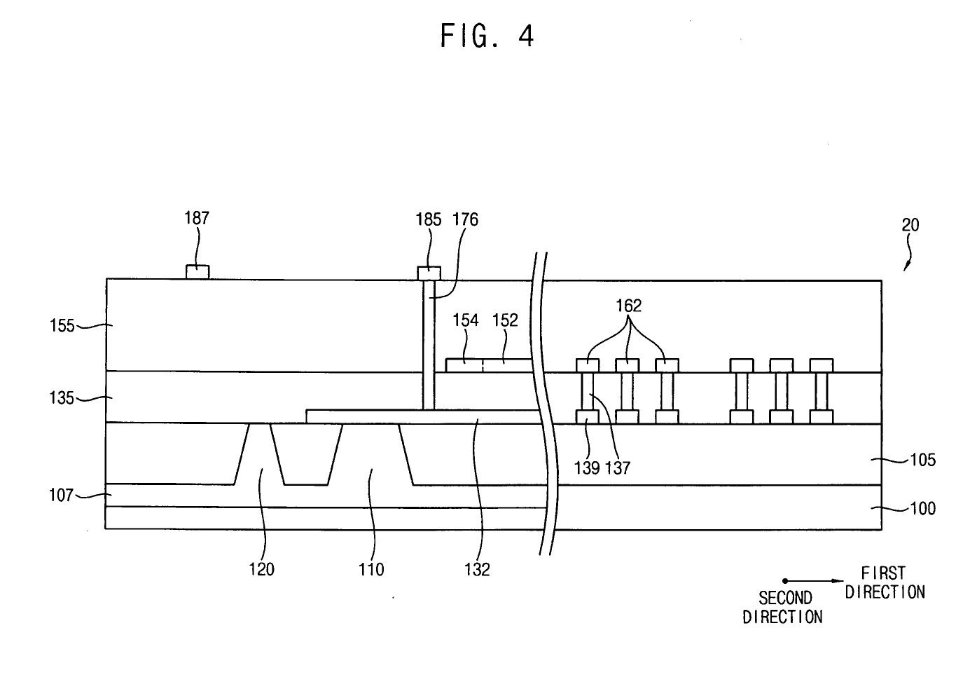

FIG. 3 is a top view illustrating a test structure of a semiconductor device in accordance with example embodiments, and FIG. 4 is a cross-sectional view taken along the line II-II′ of FIG. 3.

The test structure of FIG. 3 is substantially the same as, or similar to, that of FIG. 1 except that the test structure of FIG. 3 includes a gate antenna pattern and a gate antenna plug, and the gate line 132 of FIG. 3 extends longer than that of FIG. 1. Thus, like numerals refer to like elements, and repetitive explanations are omitted here for the sake of brevity.

Referring to FIGS. 3 and 4, a gate antenna pattern 139 is formed on the substrate 100. The gate antenna pattern 139 may have a shape substantially the same as, or similar to, that of the first conductive pattern 160. The gate antenna pattern 139 may be electrically connected to the first conductive pattern 160 by a gate antenna plug 137. The gate antenna pattern 139 may include a material substantially the same as that of the gate line 132.

The gate antenna plug 137 may be formed through the first insulating interlayer 135. The gate antenna plug 137 may include a conductive material (e.g., a metal and/or a metal nitride).

The gate antenna pattern 139 may sense plasma damage to the semiconductor device like the first conductive pattern 160. The gate antenna plug 137 may sense the plasma damage. The amount of the plasma damage sensed by the gate antenna plug 137 may depend on the number of the plugs.

If metal wirings are formed on the second insulating interlayer 155 or if other insulating interlayers are formed on the second insulating interlayer 155 and other metal wirings are formed on the insulating interlayers, other antenna patterns may be formed in the same layers as those of the metal wirings. The antenna patterns may serve (or function) as an antenna for sensing plasma damage if only (or as long as) the antenna patterns are electrically connected to the gate line 132.

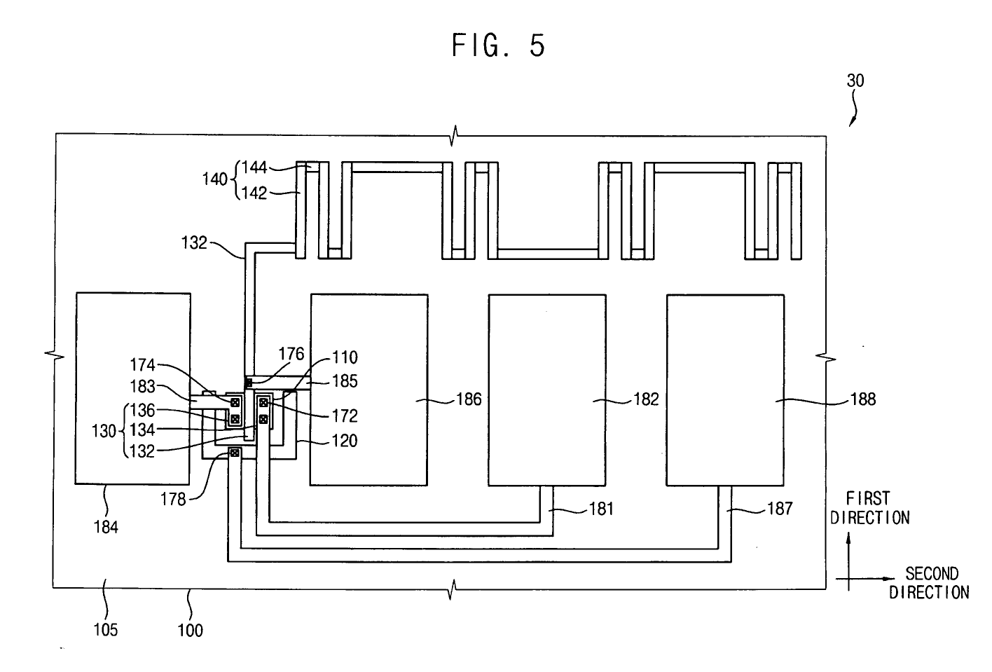

FIG. 5 is a top view illustrating a test structure of a semiconductor device in accordance with example embodiments. The test structure of FIG. 5 is substantially the same as, or similar to, that of FIG. 1 except for the location and the shape of the conductive pattern. Thus, like numerals refer to like elements, and repetitive explanations are omitted here for the sake of brevity.

Referring to FIG. 5, a second conductive pattern 140 is formed on the substrate 100.

The second conductive pattern 140 includes a third conductive line 142 and a fourth conductive line 144. The second conductive pattern 140 may have a shape substantially the same as that of the first conductive pattern 160. The second conductive pattern 140 may be used not only in aligning various circuit patterns formed on the net die region of the substrate 100, but also in sensing plasma damage to the semiconductor device, similar to the first conductive pattern 160. The second conductive pattern 140 may be referred to as a gate antenna pattern. In the example embodiments, the second conductive pattern 140 may be directly connected to the gate line 132.

If a bit line is formed on the first insulating interlayer 135, or if metal wirings are formed on the second insulating interlayer 155, other antenna patterns may be formed in the same layers as those of the bit line or the metal wirings. The antenna patterns may serve as an antenna for sensing plasma damage if only (or as long as) the antenna patterns are electrically connected to the gate line 132.

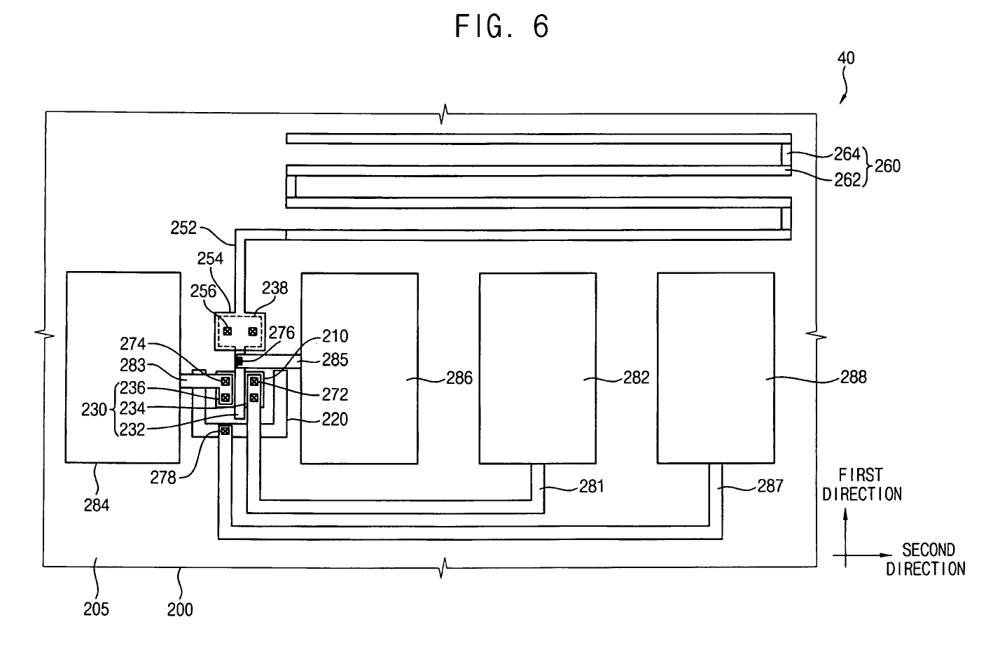

FIG. 6 is a top view illustrating a test structure of a semiconductor device in accordance with example embodiments. The test structure of FIG. 6 is substantially the same as, or similar to, that of FIGS. 1 and 2 except for the function and the shape of the conductive pattern. Thus, like numerals refer to like elements, and repetitive explanations are omitted here for the sake of brevity.

Referring to FIG. 6, a test structure 40 of the semiconductor device includes a transistor 230 on a substrate 200, a first conductive pattern 260 and a pad unit. The test structure 40 may include a bit line 252.

The substrate 200 may be divided into a net die region and a scribe lane region. In example embodiments, the test structure 40 of the semiconductor device is formed on the scribe lane region. Alternatively, the test structure 40 of the semiconductor device may be formed on the net die region. The substrate 200 may be divided into (or defined by) a field region and an active region. An isolation layer 205 may be formed in the field region. The active region has a first active region 210 and a second active region 220.

The transistor 230 includes a gate line 232 on the first active region 210, and a source region 234 and a drain region 236 at upper portions of the first active region 210 adjacent to the gate line 232. A gate line pad 238 may be formed at one end of the gate line 232 such that the gate line 232 may be electrically connected to the bit line 252.

The transistor 230 may have a configuration substantially the same as, or similar to, that of a cell transistor on the net die region. The transistor 230 may be used in measuring (or to measure) plasma damage to the semiconductor device sensed by the first conductive pattern 260.

The bit line 252 may transfer electrical signals to the transistor 230. A bit line pad 254 may be formed at one end of the bit line 252. The bit line pad 254 and the gate line pad 238 are electrically connected to each other by a bit line plug 256. The bit line plug 256 is formed through a first insulating interlayer (not shown), which is formed on the substrate 200 to cover the gate line 232. The bit line 252 and the bit line pad 254 are formed on the first insulating interlayer.

The first conductive pattern 260 includes a first conductive line 262 and a second conductive line 264. In example embodiments, a plurality of the first conductive lines 262 is formed. Each of the first conductive lines 262 extends in a second direction. The second conductive line 264 connects the first conductive lines 262 to each other. In example embodiments, a plurality of the second conductive lines 264 is formed. Each of the second conductive lines 264 extends in a first direction substantially perpendicular to the second direction.

The first conductive pattern 260, particularly, the first conductive line 262 may prevent (or reduce) damage to various circuit patterns on the substrate 200 during processes such as a chemical mechanical polishing (CMP) process. Circuit patterns formed at a peripheral portion of the substrate 200 may be easily damaged. As such, patterns having the same structure and shape as those of the real circuit patterns but not actually functioning are formed such that damage to the real circuit patterns is reduced (or prevented). As such, the first conductive pattern 260 may serve as a dummy pattern.

The first conductive pattern 260 may serve as an antenna sensing plasma damage to the test structure of the semiconductor device. The first conductive pattern 260 may be referred to as a bit line antenna pattern.

The first conductive pattern 260 may have various shapes if only (or as long as) the first conductive pattern 260 simultaneously serves as a dummy pattern and an antenna. Even though the first conductive pattern 260 shown in FIG. 6 has a zigzag shape, the second conductive line 264 may have a long bar (or rectangular) shape extending in the first direction. The second conductive line 264 connects ends of the first conductive lines 262 that are located at the same side (or adjacent to each other). In this case, the first conductive pattern 260 may have a comb-like shape. The first conductive pattern 260 may have any shape if only (or as long as) each portion of the first conductive pattern 260 is connected to each other, and the first conductive pattern 260 is connected to the gate line 232.

The pad unit includes a source pad 282, a drain pad 284, a gate pad 286 and a bulk pad 288. The pads 282, 284, 286 and 288 are formed on a second insulating interlayer (not shown). The second insulating interlayer is formed on the first insulating interlayer to cover the bit line 252, the bit line pad 254 and the first conductive pattern 260.

The source pad 282 may be connected to the source region 234 by a source pad connection line 281 on the second insulating interlayer and a first plug 272 through the first and second insulating interlayers. The drain pad 284 may be connected to the drain region 236 by a drain pad connection line 283 on the second insulating interlayer and a second plug 274 through the first and second insulating interlayers. The gate pad 286 may be connected to the gate line 232 by a gate pad connection line 285 on the second insulating interlayer and a third plug 276 through the first and second insulating interlayers. The bulk pad 288 may be connected to the second active region 220 by a bulk pad connection line 287 on the second insulating interlayer and a fourth plug 278 through the first and second insulating interlayers. The second active region 220 may be formed at a portion of the substrate 200. The second active region 220 may serve as a path by which electrical signals pass. The electrical signals may be applied to a well region (not shown) formed at a portion of the substrate 200.

The order and the locations of the pads 282, 284, 286 and 288 may be changed.

In the test structure of the semiconductor device having the above elements, the first conductive pattern 260 may serve not only as an antenna for sensing plasma damage, but also as a dummy pattern for reducing etching damage to the circuit patterns. As such, the scribe lane region on which the test structure and the dummy pattern are formed may have a reduced area. As such, a semiconductor device according to example embodiments may have a higher integration degree. If a semiconductor device includes a test structure and a dummy pattern on a net die region, a net die region in accordance with example embodiments may have a relatively smaller area compared to that on which the test structure and the dummy pattern are formed independently. As such, the semiconductor device may have a higher integration degree.

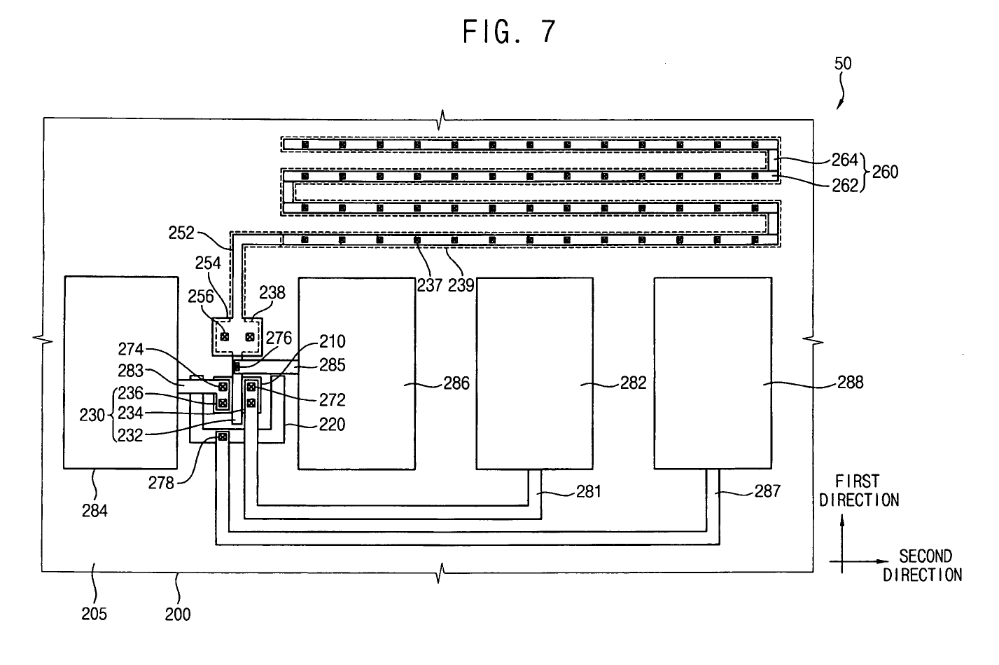

FIG. 7 is a top view illustrating a test structure of a semiconductor device in accordance with example embodiments. The test structure of FIG. 7 is substantially the same as, or similar to, that of FIG. 6 except that the test structure of FIG. 7 further includes a gate antenna pattern and a gate antenna plug, and the gate line 132 of FIG. 7 extends longer than that of FIG. 6. Thus, like numerals refer to like elements, and repetitive explanations are omitted here for the sake of brevity.

Referring to FIG. 7, a gate antenna pattern 239 is formed on the substrate 200. The gate antenna pattern 239 may have a shape substantially the same as, or similar to, that of the first conductive pattern 260. The gate antenna pattern 239 may be electrically connected to the first conductive pattern 260 by a gate antenna plug 237. The gate antenna plug 237 may be formed through the first insulating interlayer (not shown).

The gate antenna pattern 239 may sense plasma damage to the semiconductor device, similar to the first conductive pattern 260. The gate antenna plug 237 may sense the plasma damage.

If metal wirings are formed on the second insulating interlayer (not shown), other antenna patterns may be formed in the same layers as those of the metal wirings.

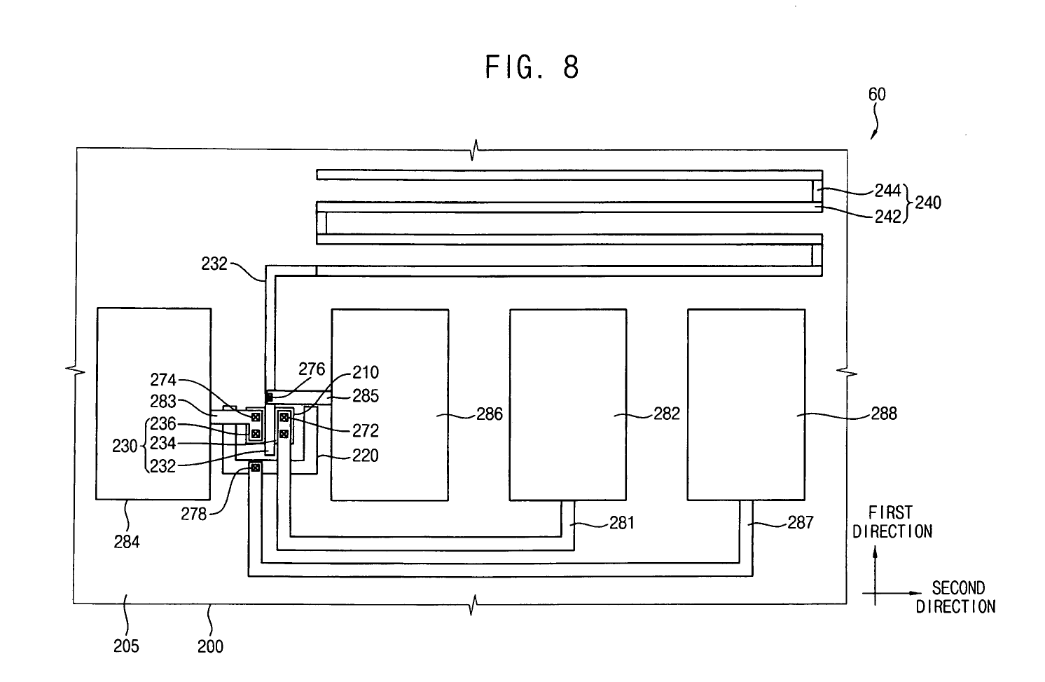

FIG. 8 is a top view illustrating a test structure of a semiconductor device in accordance with example embodiments. The test structure of FIG. 8 is substantially the same as, or similar to, that of FIG. 5 except for the location and the shape of the conductive pattern. Thus, like numerals refer to like elements, and repetitive explanations are omitted here for the sake of brevity.

Referring to FIG. 8, a second conductive pattern 240 is formed on the substrate 200.

The second conductive pattern 240 includes a third conductive line 242 and a fourth conductive line 244. The second conductive pattern 240 may have a shape substantially the same as that of the first conductive pattern 260. The second conductive pattern 240 may be used not only in reducing the etching damage to the circuit patterns, but also in sensing plasma damage to the semiconductor device, similar to the first conductive pattern 260. The second conductive pattern 240 may be referred to as a gate antenna pattern. In the example embodiments, the second conductive pattern 240 may be directly connected to the gate line 232.

If a bit line is formed on the first insulating interlayer (not shown), or if metal wirings are formed on the second insulating interlayer (not shown), other antenna patterns may be formed in the same layers as those of the bit line or the metal wirings.

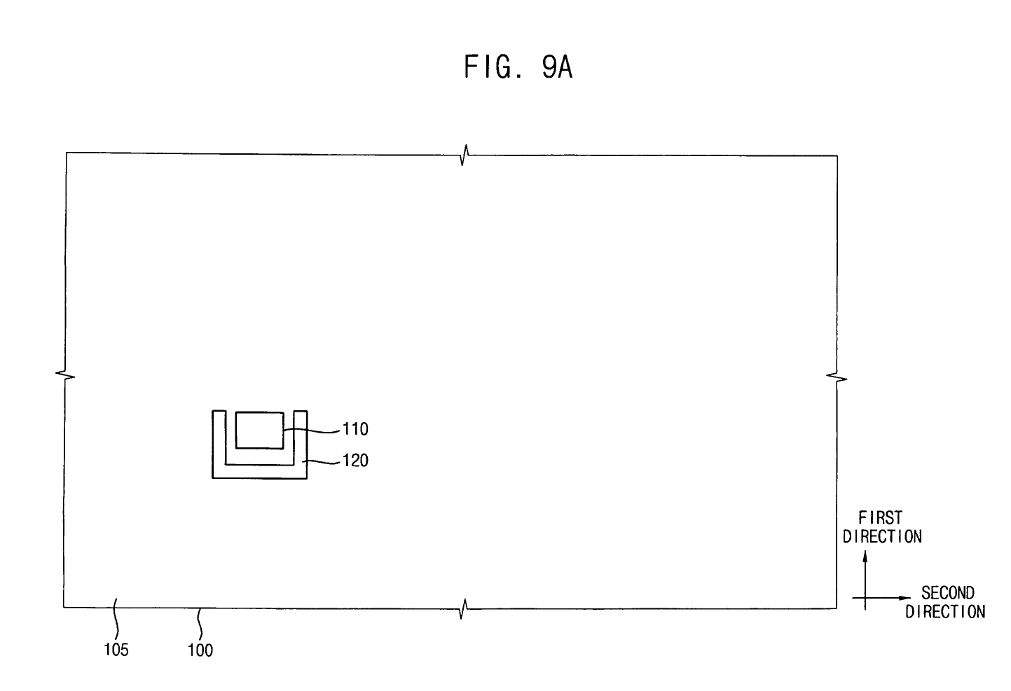

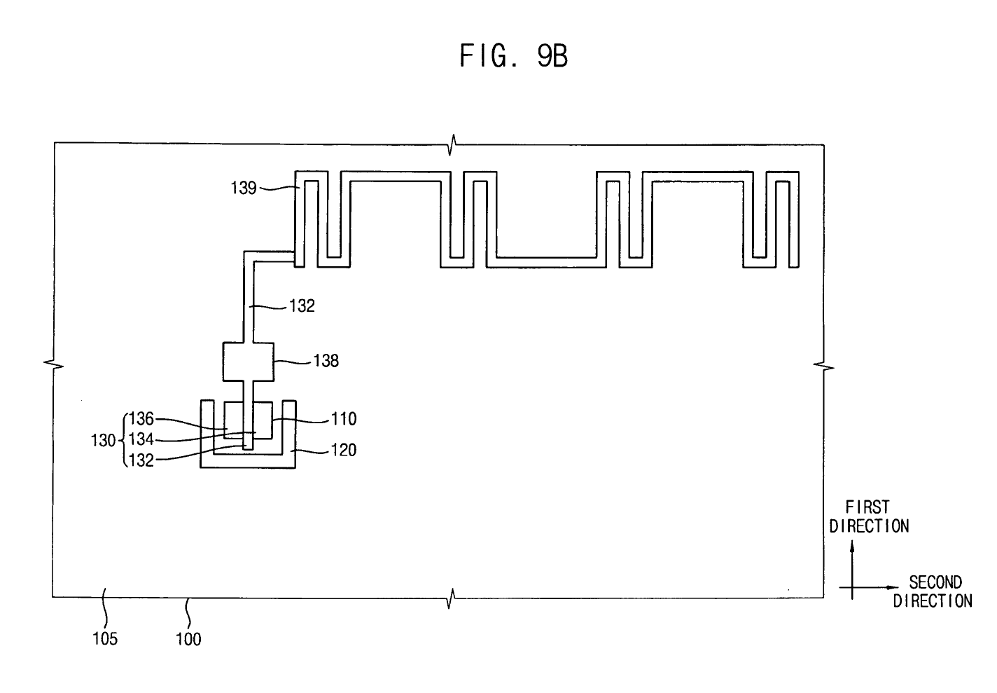

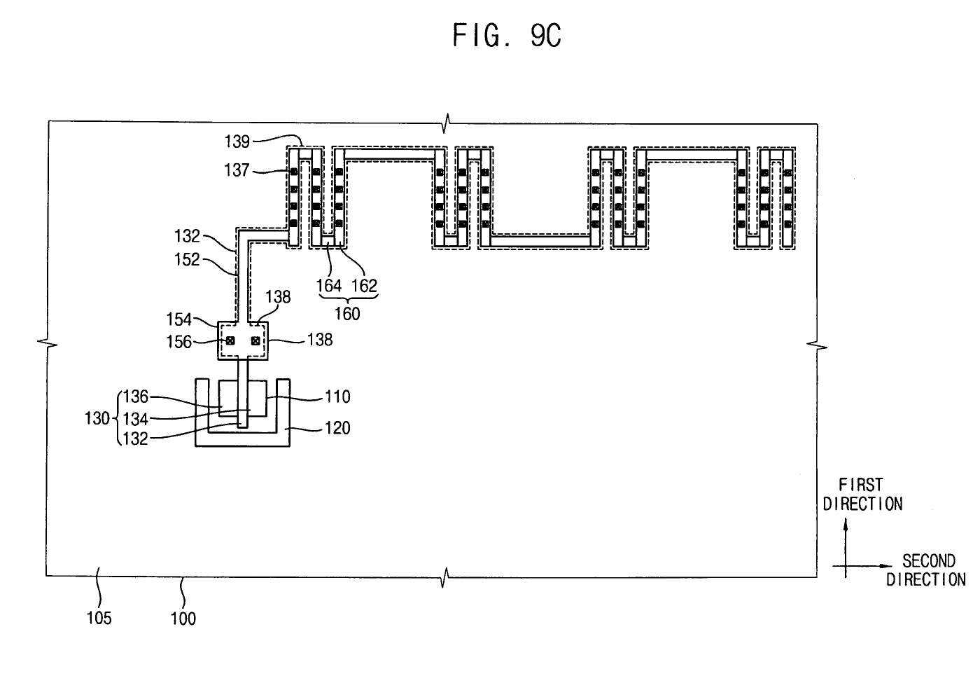

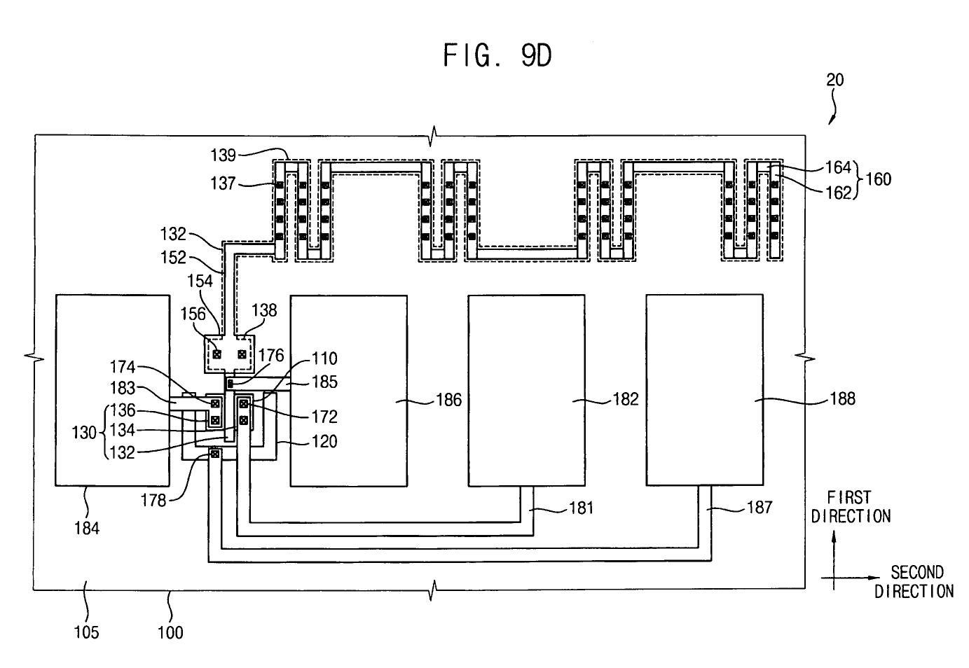

FIGS. 9A to 9D are top views illustrating a method of forming a test structure of a semiconductor device in accordance with example embodiments. Although a method of forming the test structure of FIGS. 3 and 4 is illustrated in FIGS. 9A to 9D, the scope of the example embodiments is not limited to the above method. If the gate antenna pattern 139 and the gate antenna plug 137 is omitted in FIG. 9B, then the above method may be applied to a method of forming the test structure of FIGS. 1 and 2. A method of forming the test structure of FIG. 5 may be easily understood by those skilled in the art from the following method.

Referring to FIG. 9A, an isolation layer 105 is formed on a substrate 100 to define a first active region 110 and a second active region 120. The isolation layer 105 may be formed by a shallow trench isolation (STI) process or a local oxidation of silicon (LOCOS) process. An ion implantation process may be performed on the substrate 100 to form a well region 107 (see FIG. 4) at a portion of the substrate 100. The second active region 120 has a “C” (or “U”) shape in FIG. 9A. However, example embodiments are not limited thereto. The second active region 120 may have any other shape.

Referring to FIG. 9B, a transistor 130 is formed on the first active region 110. A gate antenna pattern 139 is formed on the substrate 100.

An insulation layer (not shown) may be formed on the substrate 100. The insulation layer may be formed using an oxide, a nitride and/or an oxynitride. The insulation layer may be formed by a chemical vapor deposition (CVD) process, a low pressure chemical vapor deposition (LPCVD) process, a plasma enhanced chemical vapor deposition (PECVD) process, a high density plasma chemical vapor deposition (HDP-CVD) process, or a like process.

A first conductive layer may be formed on the insulation layer using doped polysilicon, a metal and/or a metal silicide. The first conductive layer may be formed by a CVD process, an atomic layer deposition (ALD) process, an HDP-CVD process, or similar process.

A photoresist pattern (not shown) may be formed on the first conductive layer. The first conductive layer and the insulation layer may be partially removed by an etching process using the photoresist pattern as an etching mask to form a gate line 132, a gate line pad 138 and a gate antenna pattern 139. The gate line 132 may include a gate insulation layer (not shown) and a gate electrode (not shown). The gate antenna pattern 139 may include a gate antenna insulation layer (not shown) and a gate antenna electrode (not shown).

Impurities may be implanted onto (or into) the first and second active regions 110 and 120 by an ion implantation process. A source region 134 and a drain region 136 may be formed at upper portions of the first active region 110 adjacent to the gate line 132. The gate line 135, the source region 134 and the drain region 136 constitute (or form) the transistor 130.

In example embodiments, the gate line 132 is formed to extend in a first direction. The gate antenna pattern 139 has a zigzag shape including a plurality of first portions each of which extends in the first direction and a plurality of second portions each of which extends in a second direction substantially perpendicular to the first direction. The gate line 132 is connected to the gate line pad 138 and the gate antenna pattern 139.

Referring to FIG. 9C, a first insulating interlayer 135 (see FIG. 4) is formed on the substrate 100 to cover the transistor 130, the gate line pad 138 and the gate antenna pattern 139. The first insulating interlayer 135 may be formed using an oxide, a nitride and/or an oxynitride. The first insulating interlayer 135 may be formed using a CVD process, an LPCVD process, a PECVD process, an HDP-CVD process or a similar process.

A bit line plug 156 and a gate antenna plug 137 may be formed through the first insulating interlayer 135 on the gate line pad 138 and the gate antenna pattern 139, respectively.

Openings (not shown) may be formed through the first insulating interlayer 135 to partially expose the gate line pad 138 and the gate antenna pattern 139. A second conductive layer may be formed on the first insulating interlayer 135 to fill up the openings by performing a CVD process, an ALD process, an HDP-CVD process or similar process using a metal and/or a metal nitride. An upper portion of the second conductive layer on the first insulating interlayer 135 may be removed by a chemical mechanical polishing (CMP) process and/or an etch-back process, forming the bit line plug 156 and the gate antenna plug 137 electrically connected to the gate line pad 138 and the gate antenna pattern 139, respectively.

A third conductive layer may be formed on the first insulating interlayer 135 using doped polysilicon, a metal and/or a metal nitride to cover the bit line plug 156 and the gate antenna plug 137. The third conductive layer may be formed by a CVD process, an ALD process, a HDP-CVD process, or similar process. The third conductive layer may be patterned to form a bit line pad 154 and a conductive pattern 160 electrically connected to the bit line plug 156 and the gate antenna plug 137, respectively. A bit line 152 may be formed.

In example embodiments, the conductive pattern 160 is formed to have a shape substantially the same as, or similar to, that of the gate antenna pattern 139. The conductive pattern 160 may be formed to have a plurality of first conductive lines 162 each of which extends in the first direction, and a plurality of second conductive lines 164 each of which extends in the second direction.

Referring to FIG. 9D, a source pad 182, a drain pad 184, a gate pad 186 and a bulk pad 188 are formed to be electrically connected to the source region 134, the drain region 136, the gate line 132 and the second active region 120, respectively.

A second insulating interlayer 155 (see FIG. 4) is formed on the first insulating interlayer 135 to cover the bit line 152, the bit line pad 154 and the conductive pattern 160. The second insulating interlayer 155 may be formed using an oxide, a nitride and/or an oxynitride. The second insulating interlayer 155 may be formed by a CVD process, an ALD process, an HDP-CVD process, or similar process.

Openings (not shown) may be formed through the first and second insulating interlayers 135 and 155 to partially expose the source region 134, the drain region 136, the gate line 132 and the second active region 120. A fourth conductive layer is formed on the second insulating interlayer 155 to fill up the openings by a CVD process, an ALD process, an HDP-CVD process, or similar process using a metal and/or a metal nitride. An upper portion of the fourth conductive layer on the second insulating interlayer 155 may be removed by performing a CMP process and/or an etch-back process, thereby forming first to fourth plugs 172, 174, 176 and 178 electrically connected to the source region 134, the drain region 136, the gate line 132 and the second active region 120, respectively.

A fifth conductive layer may be formed on the second insulating interlayer 155 and the plugs 172, 174, 176 and 178. The fifth conductive layer may be formed by a CVD process, an ALD process, an HDP-CVD process, or similar process using a metal and/or a metal nitride. The fifth conductive layer is patterned by a photolithography process using a photoresist pattern to form a source pad 182, a drain pad 184, a gate pad 186 and a bulk pad 188 electrically connected to the first to fourth plugs 172, 174, 176 and 178, respectively. The locations of the source pad 182, the drain pad 184, the gate pad 186 and the bulk pad 188 may be changed. A source pad connection line 181 that electrically connects the source pad 182 to the first plug 172, a drain pad connection line 183 that electrically connects the drain pad 184 to the second plug 174, a gate pad connection line 185 that electrically connects the gate pad 186 to the third plug 176, and a bulk pad connection line 187 that electrically connects the bulk pad 178 to the fourth plug 178, may be formed.

By the above-described processes, the test structure 20 of the semiconductor device may be formed. Further to the above elements or patterns, various types of wirings may be formed.

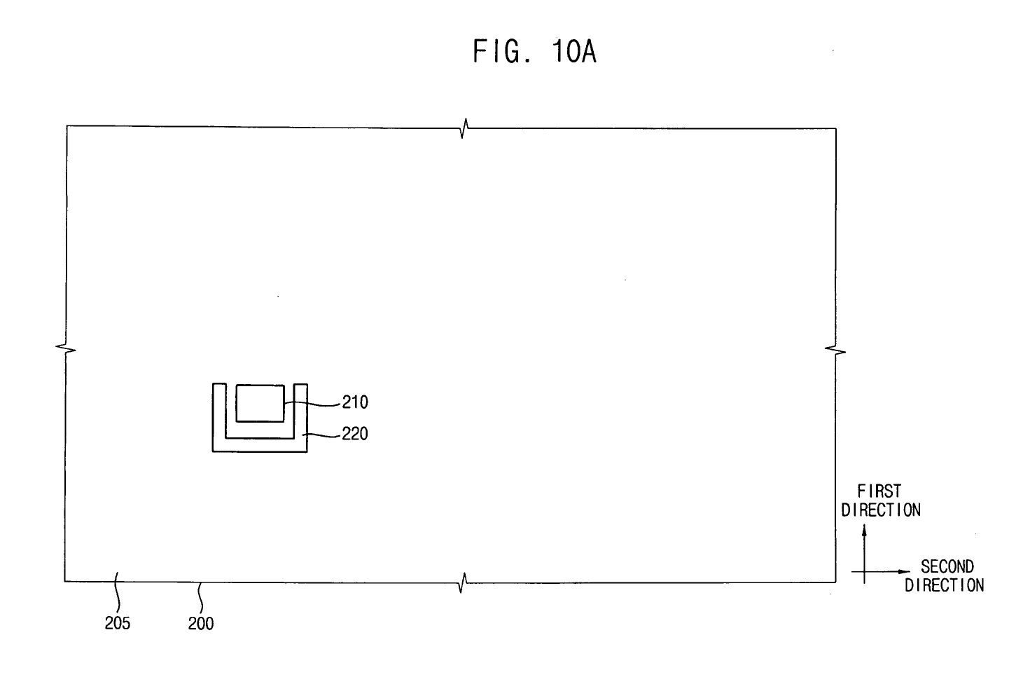

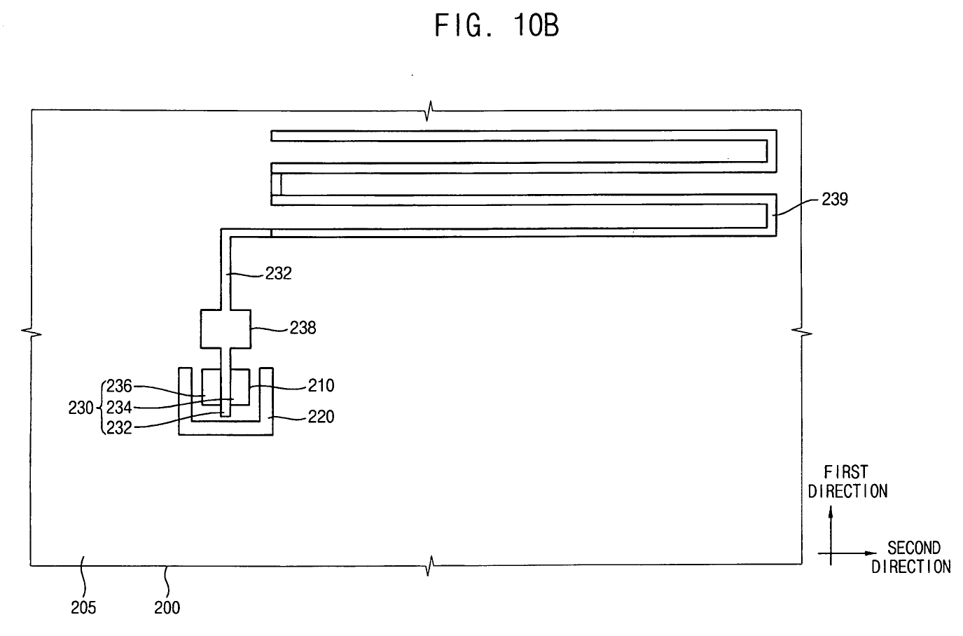

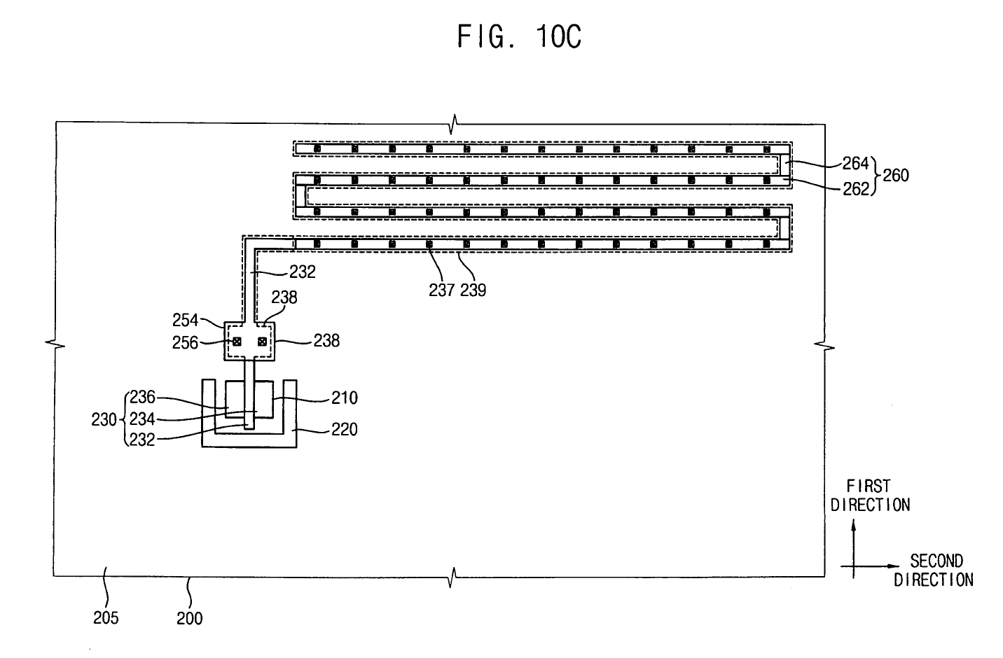

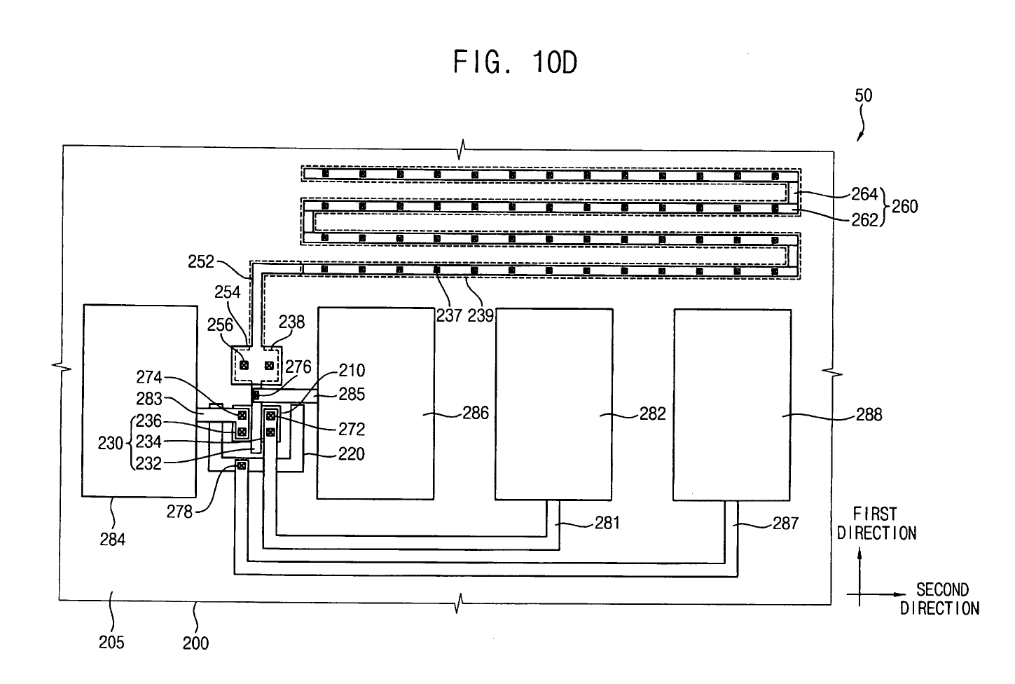

FIGS. 10A to 10D are top views illustrating a method of forming a test structure of a semiconductor device in accordance with example embodiments. Although a method of forming the test structure of FIG. 7 is illustrated in FIGS. 10A to 10D, the scope of example embodiments are not limited to the above method.

The method of forming the test structure of the semiconductor device with reference to FIGS. 10A to 10D is substantially the same as, or similar to, that of FIGS. 9A to 9D, except for the function and the shape of the conductive pattern. Thus, repetitive explanations are omitted here for the sake of brevity. If formation of the gate antenna pattern 239 and the gate antenna plug 237 is omitted in FIG. 10B, then the above method may be applied to a method of forming the test structure of FIG. 6. A method of forming the test structure of FIG. 8 may be easily understood by those skilled in the art from the following method with reference to FIGS. 10A to 10D.

Referring to FIG. 10A, an isolation layer 205 is formed on a substrate 200 to define a first active region 210 and a second active region 220. An ion implantation process may be performed on the substrate 200 to form a well region 207 (not shown) at a portion of the substrate 200.

Referring to FIG. 10B, a transistor 230 is formed on the first active region 210. A gate antenna pattern 239 is formed on the substrate 200.

A gate line 232, a gate line pad 238 and a gate antenna pattern 239 are formed. Impurities may be implanted onto (or into) the first and second active regions 210 and 220 by performing an ion implantation process. A source region 234 and a drain region 236 may be formed at upper portions of the first active region 210 adjacent to the gate line 232. The gate line 235, the source region 234 and the drain region 236 constitute (or form) the transistor 230.

In example embodiments, the gate line 232 is formed to extend in a first direction. The gate antenna pattern 239 has a zigzag shape including a plurality of first portions each of which extends in the first direction and a plurality of second portions each of which extends in a second direction substantially perpendicular to the first direction. The gate line 232 is connected to the gate line pad 238 and the gate antenna pattern 239.

Referring to FIG. 10C, a first insulating interlayer (not shown) may be formed on the substrate 200 to cover the transistor 230, the gate line pad 238 and the gate antenna pattern 239. A bit line plug 256 and a gate antenna plug 237 may be formed through the first insulating interlayer 235 on the gate line pad 238 and the gate antenna pattern 239, respectively. A bit line pad 254 and a conductive pattern 260 may be electrically connected to the bit line plug 256 and the gate antenna plug 237, respectively. A bit line 252 may be formed.

In example embodiments, the conductive pattern 260 is formed to have a shape substantially the same as, or similar to, that of the gate antenna pattern 239. The conductive pattern 260 may be formed to have a plurality of first conductive lines 262 each of which extends in the first direction, and a plurality of second conductive lines 264 each of which extends in the second direction.

Referring to FIG. 10D, a second insulating interlayer (not shown) may be formed on the first insulating interlayer 235 to cover the bit line 252, the bit line pad 254 and the conductive pattern 260. First to fourth plugs 272, 274, 276 and 278 are formed through the first and second insulating interlayers to be electrically connected to the source region 234, the drain region 236, the gate line 232 and the second active region 220, respectively. A source pad 282, a drain pad 284, a gate pad 286 and a bulk pad 288 may be electrically connected to the first to fourth plugs 272, 274, 276 and 278, respectively. A source pad connection line 281 that electrically connects the source pad 282 to the first plug 272, a drain pad connection line 283 that electrically connects the drain pad 284 to the second plug 274, a gate pad connection line 285 that electrically connects the gate pad 286 to the third plug 276, and a bulk pad connection line 287 that electrically connects the bulk pad 278 to the fourth plug 278, may be formed.

By the above-described processes, the test structure 50 of the semiconductor device may be formed. Further to the above elements or patterns, various types of wirings may be formed.

According to example embodiments, a conductive pattern included in a test structure of a semiconductor device may serve not only as an antenna for sensing plasma damage to the semiconductor device, but also as an align/overlay pattern for aligning various circuit patterns on the net die region. The conductive pattern may also serve as a dummy pattern for reducing the etching damage to the circuit patterns. A scribe lane region of a substrate on which the test structure, the align/overlay pattern and the dummy pattern are formed may have a reduced area such that the semiconductor device including the elements on the scribe lane region may have a higher integration degree. If the test structure, the align/overlay pattern and the dummy pattern are formed on a net die region of the substrate, the net die region may have a relatively reduced area such that the semiconductor device may have a higher integration degree.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A test structure of a semiconductor device, comprising:
a transistor on a substrate having circuit patterns;
a conductive pattern electrically connected to the transistor, the conductive pattern being used in aligning the circuit patterns and sensing plasma damage to the semiconductor device; and
a pad unit electrically connected to the transistor, the pad unit providing electrical signals to the transistor.

2. The test structure of claim 1, wherein the transistor includes a gate line, the conductive pattern being electrically connected to the gate line.

3. The test structure of claim 2, further comprising a bit line electrically connected to the transistor, the conductive pattern being electrically connected to the bit line.

4. The test structure of claim 3, wherein the conductive pattern includes a gate antenna pattern and a bit line antenna pattern, the gate antenna pattern and the bit line antenna pattern being connected by a plug.

5. The test structure of claim 4, further comprising a plurality of the plugs.

6. The test structure of claim 1, wherein the conductive pattern includes:
a plurality of first conductive lines each extending in a first direction, the first conductive lines being disposed at a desired distance from each other in a second direction substantially perpendicular to the first direction; and
a second conductive line extending in the second direction and connecting the plurality of first conductive lines to each other.

7. A test structure of a semiconductor device, comprising:
a transistor on a substrate having circuit patterns;
a conductive pattern electrically connected to the transistor, the conductive pattern being used in reducing etching damage to the circuit patterns and sensing plasma damage to the semiconductor device; and
a pad unit electrically connected to the transistor, the pad unit providing electrical signals to the transistor.

8. The test structure of claim 7, wherein the transistor includes a gate line, the conductive pattern being electrically connected to the gate line.

9. The test structure of claim 8, further comprising a bit line electrically connected to the transistor, the conductive pattern being electrically connected to the bit line.

10. The test structure of claim 9, wherein the conductive pattern includes a gate antenna pattern and a bit line antenna pattern, the gate antenna pattern and the bit line antenna pattern being connected by a plug.

11. The test structure of claim 10, further comprising a plurality of the plugs.

12. The test structure of claim 7, wherein the conductive pattern includes:
a plurality of first conductive lines each extending in a first direction, the first conductive lines being disposed at a desired distance from each other in a second direction substantially perpendicular to the first direction; and
a second conductive line extending in the second direction and connecting the first conductive lines to each other.

13. A method of forming a test structure of a semiconductor device, comprising:
forming a transistor on a substrate having circuit patterns;
forming a conductive pattern electrically connected to the transistor, the conductive pattern being used in aligning the circuit patterns and sensing plasma damage to the semiconductor device; and
forming a pad unit electrically connected to the transistor, the pad unit providing electrical signals to the transistor.

14. The method of claim 13, wherein forming the transistor includes forming a gate line, the conductive pattern being electrically connected to the gate line.

15. The method of claim 14, further comprising forming a bit line electrically connected to the transistor, the conductive pattern being electrically connected to the bit line.

16. The method of claim 15, wherein forming the conductive pattern includes:
forming a gate antenna pattern and a bit line antenna pattern; and
connecting the gate antenna pattern and the bit line antenna pattern by a plug.

17. The method of claim 16, wherein the conductive pattern includes a plurality of the plugs.

18. The method of claim 13, wherein forming the conductive pattern includes:
forming a plurality of first conductive lines each extending in a first direction, the first conductive lines being disposed at a desired distance from each other in a second direction substantially perpendicular to the first direction; and
forming a second conductive line extending in the second direction and connecting the first conductive lines to each other.

19. A method of forming a test structure of a semiconductor device, comprising:
forming a transistor on a substrate having circuit patterns;
forming a conductive pattern electrically connected to the transistor, the conductive pattern being used in reducing etching damage to the circuit patterns and sensing plasma damage to the semiconductor device; and
forming a pad unit electrically connected to the transistor, the pad unit providing electrical signals to the transistor.

20. The method of claim 19, wherein forming the transistor includes forming a gate line, the conductive pattern being electrically connected to the gate line.

21. The method of claim 20, further comprising forming a bit line electrically connected to the transistor, the conductive pattern being electrically connected to the bit line.

22. The method of claim 21, wherein forming the conductive pattern includes:
forming a gate antenna pattern and a bit line antenna pattern; and
connecting the gate antenna pattern and the bit line antenna pattern by a plug.

23. The method of claim 22, wherein the conductive pattern includes a plurality of the plugs.

24. The method of claim 19, wherein forming the conductive pattern includes:
forming a plurality of first conductive lines each extending in a first direction, the first conductive lines being disposed at a desired distance from each other in a second direction substantially perpendicular to the first direction; and
forming a second conductive line extending in the second direction and connecting the first conductive lines to each other.
